(19) United States
(12) Patent Application Publication
(10) Pub. No.: US 2010/0153788 A1
(43) Pub. Date: Jun. 17, 2010

(54) SEMICONDUCTOR DEVICE

(75) Inventor: Yoshihiro Nakagawa, Minato-ku (JP)

Correspondence Address: SUGHRUE MION, PLLC, 2100 PENNSYLVANIA AVENUE, N.W., SUITE 800, WASHINGTON, DC, 20037, US

(73) Assignee: Nec Corporation, Minato-ku Tokyo (JP)

(21) Appl. No.: 12/294,224

(22) PCT Filed: Jan. 22, 2007
(86) PCT No.: PCT/JP2007/050909

§ 371 Date: Sep. 23, 2008

(30) Foreign Application Priority Data
Mar. 24, 2006 (JP) 2006 083623

(51) Int. Cl. G06F 11/34; H01L 23/02

(52) U.S. Cl. 714/45; 257/678; 714/E11.205; 257/E23.18

(57) ABSTRACT

The present invention aims at providing an integrated circuit device which can perform on-chip tracing by using a system installed with the same chip as that of a mass produced product, and comprises: at least one or more kinds of first chips equipped with a circuit for performing data processing; and a second chip equipped with a circuit for tracing the operation of said circuit installed a the first chip, wherein a signal between said first chip and said second chip is transmitted by signal transmission utilizing electromagnetic induction.

### TECHNICAL FIELD

The present invention relates to a trace function which is used in the debugging of a system equipped with a processor, and to a semiconductor device equipped with a chip having a trace function in the same package with the processor.

### BACKGROUND ART

When a bug occurs in the development of application software which operates in a system equipped with a processor, one basic method to deal with bugs is to verify the contents of instructions and the contents of the memory and register by using breakpoints and by performing step execution. However, bugs which have unexpectedly occurred between application software and hardware can not be dealt with by the aforementioned method. This is because a real environment cannot be reproduced by the step execution, and simply repeating activation, deactivation, and step execution of a processor tends not to produce problems. In particular, malfunctions which are caused by the fluctuation or noise of the power supply, which occurs when a particular instruction is executed, can not be found by the step execution, and may occur only while a system including a processor operates at its full speed. Therefore, a need arises to perform debugging in a similar state similar to or the same state as a real environment.

One solution to the above described problem is to dismount the processor in the system and install an emulator ICE instead. The ICE has similar functions to those of the processor, and can monitor information such as executed instructions, data addresses, data, and so on.

However, it is necessary to create an emulator which has processor functions for each processor equipped in the system to be produced, and therefore there are problems in development cost, development time, and in other areas. Thus, this has led to the development of a trace mechanism that has a monitoring function of an ICE is embedded in a processor chip.

A processor equipped system is made up of a processor chip and a storage memory RAM. The processor chip includes a processor core, a debug interface, and a peripheral circuit. Further, the debug interface includes an external interface and a trace mechanism. The processor core repeats a cycle of fetching and executing an instruction thereby reading out data stored in RAM etc. and processing the data thereafter storing that data in RAM.

The trace mechanism monitors the operation of the processor core and transfers information such as the internal signal, the memory access history, and the memory data of the core to the outside of the system through the external interface. This information is utilized for debugging application software.

As the processor becomes faster and more advanced, the system itself is mounted in a single chip, which is called a system LSI. When the circuit scale is small, it is possible to trace the operation of the processor and the data in the memory from the pin of each processor, but when it comes to a system LSI, tracing the state of the processor core from the pin becomes difficult. This is because it becomes impossible to access the information in the processor core through the pin.

Furthermore, when a point is reached at cache is used in a processor chip for enhancing the processing performance of the processor, it is required to trace not only the above described information between the processor core and the RAM, but also the exchange of data between the processor core and cache. The data exchange between the processor and cache is faster and larger in amount than the data exchange between the processor and RAM. The band width thereof becomes a little less than 100 times faster than the operating speed of the processor core. Therefore, tracing must be faster and larger in amount. For this reason, an ETM is used which performs tracing at a higher speed and in a larger volume than the above described trace mechanism for performing tracing between the processor core and the RAM.

When the operating speed of the processor core further increases, the circuit scale necessary for tracing becomes larger, and an increase in the area occupied by the ETM becomes a significant problem and therefore, in some cases, the ETM is not installed due to considerations of manufacturing cost etc. despite the recognized difficulty in debugging.

Generally, such trace mechanisms and the ETMs are used only in the debugging of application software and are not put into operation in a mass production system and therefore they are unnecessary after the software is completed. Since a trace mechanism and an ETM are typically formed in the same chip, this tends to cause the cost of the chip to increase by the amount corresponding to the area of the processor chip occupied by the trace mechanism.

As a solution thereof, the technology disclosed in Patent Document 1 (Japanese Patent Laid-Open No. 2004-102331) proposes that the trace mechanism be fabricated as a trace chip separate from the processor chip and be embodied as a SIP (System in Package) by utilizing wire bonding, flip-chip mounting, etc.

FIG. 1A is a sectional view of a semiconductor device in which the trace mechanism is used as a separate chip utilizing the technology disclosed in Patent Document 1.

As shown in FIG. 1A, it is suggested that as a result of trace chip 10 not being included in the mass production system, cost reduction can be achieved compared with a system which uses a processor chip including a conventional trace mechanism.

Patent Document 1: Japanese Patent Laid-Open No. 2004-102331.

However, when cache is installed in a system LSI or processor and a large bandwidth is required for tracing, as in an ETM, it is not possible to form a SIP by using a trace mechanism as a separate chip and by using wire bonding. This is because a connection by using wire bonding cannot secure the necessary bandwidth.

Further, as shown in FIG. 1B, when data is moved from processor chip 1 to memory chip 13, it is moved by way of trace chip 10. Thus, a time delay occurs, in a trace chip 10, and it is different from mass produced chip.

Further, as shown in FIG. 1C, connecting the processor core chip and the trace chip by utilizing flip-chip mounting which has a larger bandwidth than wire bonding will solve the problem relating to bandwidth; however, since power supply to memory chip 13 is performed through trace chip 10, the environment that is used, while tracing is occurring, becomes different from the environment that is normally used, thereby disabling to perform accurate debugging. In order to solve this problem, although it is possible to add a power supply stabilization circuit to the power supply of each chip thereby reducing the effect of the fluctuation of the power supply, this will result in an increase in the chip area and therefore an increase in production cost.

From the above described reason, when debugging application software in an information processing system equipped with a processor, it has been difficult to incorporate the trace mechanism of a processor core which operates at a high speed into a chip that is separate from the processor chip, thereby tracing and processing the data flow is done by the tracing mechanism of the processor core.

The present invention has been made to solve the above described problem, and its first objective is to provide an integrated circuit device which can perform tracing of a chip by using a system equipped with the same chip as that of a mass product chip.

A second objective thereof is to provide an integrated circuit device which enables performing tracing even without adding a debugging circuit to a mass product chip.

A third objective thereof is to provide an integrated circuit device which enables performing the tracing of a processor even when the operating frequency of the processor which performs tracing is increased.

A fourth objective thereof is to provide a semiconductor device which can acquire trace signals for debugging in approximately the same operational environment as that of a mass product chip.

### DISCLOSURE OF THE INVENTION

The semiconductor device according to claim 1 comprises at least one or more kinds of first chips for performing data processing, and a second chip for monitoring the operation of a circuit mounted on the first chip and tracing the operation thereof.

The data necessary for the monitoring the first chip is acquired by signal transmission between the first and second chips utilizing electromagnetic induction.

Since the first and second chips are separately configured, and if the second chip is not installed in a product manufactured through mass production, no debugging circuit will be added to the mass product chip, it becomes possible to reduce the manufacturing cost through the reduction of chip area. Moreover, since the second chip performs tracing by using the first chip installed in a product manufactured through mass product, it becomes possible to perform tracing by use of approximately the same semiconductor device as that of the mass product chip. Further, since the first chip and the second chip are not mechanically connected, it is possible to perform tracing in approximately the same condition as the actual condition for performing tracing in mass product chip.

The semiconductor device according to claim 2 comprises information inside a first chip, and a second chip for monitoring the data exchange between the first chip and a third chip and tracing the operation thereof. The data necessary for monitoring the first chip and the second chip is acquired by signal transmission utilizing electromagnetic induction between the first and third chips and the second chip. Since the first and third chips and the second chip are separately configured, it is possible to achieve a similar effect to that of the semiconductor device according to claim 1. Further, since the second chip performs tracing by using the first and third chips installed in a mass-produced product, it becomes possible to perform tracing using approximately the same semiconductor device as that of a mass product chip. Further, since the signal transmission between the first chip and the third chip is the same as that of a mass produced chip, it is possible to perform tracing in approximately the same operating as that of a mass produced chip. Furthermore, since the first chip and the second chip are not mechanically connected, it is possible to perform tracing in approximately the same condition as the operating of mass product chip.

The semiconductor device according to claim 3 is the semiconductor device according to claim 1 or 2, which comprises wiring through which data, that is needed for tracing, flows and a part of the which is formed into the shape of a loop. Since the above described loop-shaped wiring enables signal transmission by electromagnetic induction and thus no trace circuit will be added to the first chip and the third chip, it is possible to reduce the production cost of the bulk product. Further, since the effect on the system of the bulk product is very small during tracing, it is possible to perform effective debugging.

The semiconductor device according to claim 4 is the semiconductor device according to any of claims 1 to 3, in which power supply to the second chip includes independent power supply wiring via neither the first chip nor the third chip.

Since independent power supply to the second chip is enabled and the presence or absence of the action of the second chip does not affect the first chip and the third chip, it is possible to perform tracing in approximately the same condition as the operating of the mass product chip.

The semiconductor device according to claim 5 is the semiconductor device according to any of claims 1 to 4, which comprises a package in which the first chip and the third chip are sealed, and a second package in which the second chip is sealed.

Since the acquisition of trace information is enabled by placing the package sealed second chip of the mass produced product on top of the system itself, it is possible to perform tracing in the same environment as the operation environment of the bulk product.

In the semiconductor device according to clam 5 or 6, it is possible achieve a similar effect to that of the semiconductor device according to claim 1, 2, 4, or 5, by using another signal transmission method utilizing the above described electromagnetic induction for the connection between the first chip or third chip and the second chip.

According to the semiconductor device according to claim 1, since the first and second chips are separately configured, and if the second chip is not installed in a mass product chip, no debugging circuit will be added to the mass product chip, it is made possible to reduce the manufacturing cost through the reduction of chip area. Moreover, since the second chip performs tracing by using the first chip installed in the mass product chip, it becomes possible to perform tracing by use of approximately the same semiconductor device as that of the mass product chip. Furthermore, since the first chip and the second chip are not mechanically connected, it is made possible to perform tracing in approximately the same condition as the operating of the mass product chip.

According to the semiconductor device according to claim 2, since the first and third chips, and the second chip are configured separately, a similar effect to that of the semiconductor device according to claim 1 can be achieved. Further, since the second chip performs tracing using the first and the third chips which are installed in a mass produced product, it becomes possible to perform tracing using approximately the same semiconductor device as that of the mass produced product. Further, since the signal transmission between the first chip and the third chip is the same as that for the mass product chip, performing tracing in approximately the same environment as the operating of the mass product chip is made possible. Moreover, since the first chip and the second chip are not mechanically connected, performing tracing in approximately the same condition as the operating of the mass product chip is made possible.

According to the semiconductor device according to claim 3, since signal transmission by electromagnetic induction is enabled by the above described loop-shape wiring and since no circuit for tracing is added to the first chip or the third chip, reducing the production cost of the mass product chip is made possible. Further, since the effect on the system of the bulk product is very small during tracing, performing effective debugging is made possible.

According to the semiconductor device according to claim 4, since independent power supply to the second chip is enabled and since the presence or absence of the action of the second chip does not affect the first chip and the third chip, performing tracing in approximately the same condition as the operating condition of the mass product chip is made possible.

According to the semiconductor device according to claim 5, since the acquisition of trace information is enabled by placing the package sealed second chip of the mass produced product on top of the system itself, performing tracing in the same environment as the operating environment of the mass product chip is made possible.

According to the semiconductor device according to claim 5 or 6, achieving a similar effect to that of the semiconductor device according to claim 1, 2, 4, or 5 is made possible.

### BRIEF DESCRIPTION OF THE DRAWINGS

FIG. 1A is a sectional view to show the configuration of a conventional example;

FIG. 1B is a sectional view to show the configuration of a conventional example;

FIG. 1C is a sectional view to show the configuration of a conventional example;

FIG. 2A is a sectional view of a semiconductor device of a SIP used in a system which provides a mass product chip for which debugging is not performed;

FIG. 2B is a sectional view of a semiconductor device having a SIP configuration after trace chip 10 is mounted;

FIG. 2C shows an example in which flip-chip mounting utilizing solder ball 15 is performed for the connection between processor chip 1 and frame 6;

FIG. 3 is a block diagram to conceptually show the configuration within processor core 1;

FIG. 4A is a circuit diagram of wireless signal transmission mechanism transmission circuit 12ATX;

FIG. 4B is a circuit diagram of reception circuit 12BRX;

FIG. 4C is a waveform diagram to show the operations of wireless signal transmission mechanism transmission circuit 12ATX and reception circuit 12BRX;

FIG. 5 shows a second exemplary embodiment;

FIG. 6A is a sectional view of a mass produced chip without any trace chip;

FIG. 6B is a sectional view when trace chip 10 is mounted;

FIG. 7 shows alternative means for non-contact signal transmission mechanism (transmission) 12A;

FIG. 8 shows an example of the circuit diagram of reception coil 6 and reception circuit 7;

FIG. 9 shows current which flows through loop 5 when the output of circuit 1 is in a voltage mode and shows the signal generated in reception coil 6 and the reception result of reception circuit 7;

FIG. 10 shows the result when output of circuit 1 is in a current mode; and

FIG. 11 shows a semiconductor device which utilizes a through electrode for signal transmission between chips.

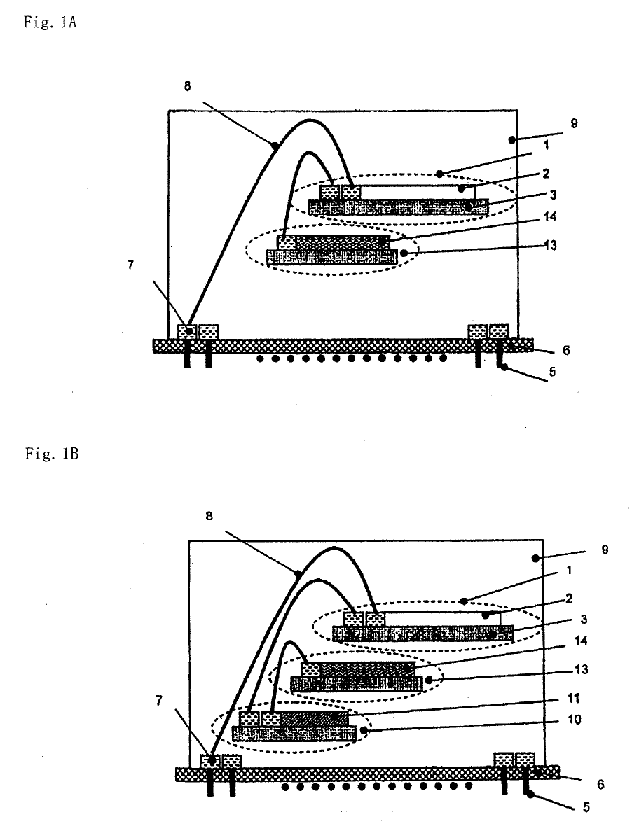

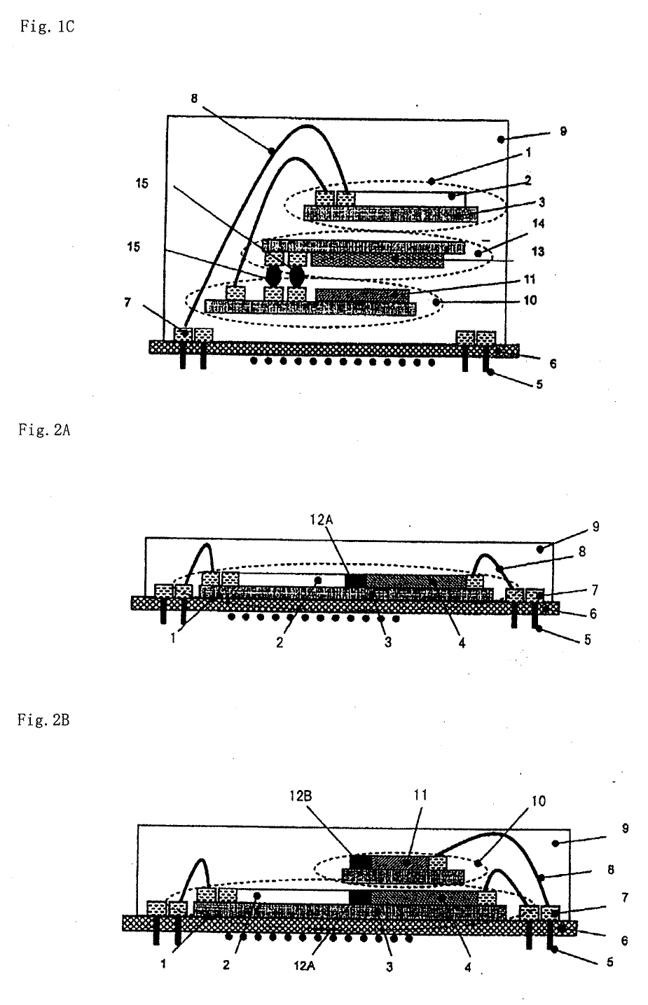

### DESCRIPTION OF SYMBOLS

1 Processor chip
2 Processor core
3 Substrate
4 Cache
5 Pin
6 Frame
7 Pad
8 Wire
9 Mold
12A Non-contact signal communication mechanism (transmission)
12B Non-contact signal communication mechanism (reception)

### BEST MODE FOR CARRYING OUT THE INVENTION

### First Exemplary Embodiment

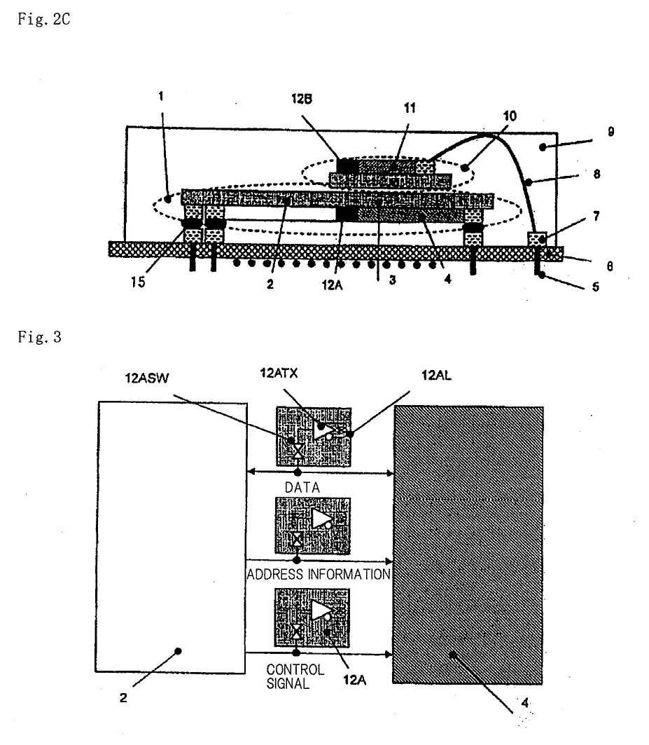

FIG. 2 is a schematic sectional view to show a first exemplary embodiment of the present invention. The integrated circuit device of the present exemplary embodiment has a SIP (System in Package) configuration and a trace chip is provided within a semiconductor device to internally perform tracing.

FIG. 2A is sectional view of a semiconductor device of a SIP used for a system which provides a mass product chip for which debugging has not been performed. As shown in FIG. 2A, a bulk product has only processor chip 2, a mass product chip has only processor chip 2 to which that is needed for tracing has not been installed. This semiconductor device includes a processor chip provided in mold 9, and frame 6 having a plurality of pins 5 and pads 7 for external input/output of the package.

Processor chip 1 includes processor core 2, cache 4, non-contact signal communication mechanism (transmission) 12A which transmits necessary information for tracing between processor core 2 and cache 4 to trace chip 10, and pad 7, which are formed on substrate 3. Inputting/outputting of data to/from processor chip 1, supply of control signals and power supply are performed through wire 8, pad 7, and pin 5.

FIG. 2B is a sectional view of a semiconductor device of a SIP configuration after trace chip 10 is implemented.

Trace chip 10 is provided on top of processor chip 1. The trace chip includes trace mechanism 11, non-contact signal communication mechanism (reception) 12B, and pad 7. Trace mechanism 11 includes the function of creating a trace signal and an external interface. It is effective to configure the location where the trace chip has been installed such that non-contact communication mechanisms 12A and 12B overlap one another. This communication mechanism transmits the necessary information to the trace chip for tracing of the processor chip. From this information, trace mechanism 11 creates trace information. The trace information obtained by trace chip 10 is inputted and outputted to and from the outside of the chip by using pad 7 and pin 5. Debugging of software is enabled by analyzing the trace information.

Further, power supply to trace chip 10 is provided from pin 5 which is different from the one for power supply for processor chip 1. Since the power supply of processor chip 1 and the power supply of trace chip 10 are separated, the operation environment of the power supply of processor chip 1 will not be very different from that of a mass product chip which is not equipped with trace chip 10, even during tracing.

Although the first exemplary embodiment has assumed only the signal transmission from processor chip 1 to trace chip 10, signal transmission from trace chip 10 to processor chip 1 is also possible. If that is the case, such signal transmission can be realized by providing non-contact signal communication mechanism (transmission) 12A in trace chip 10 and by providing non-contact signal communication mechanism (reception) 12B in processor chip 1.

In FIG. 2B, processor chip 1 and frame 6 are connected by wire 8. Then, FIG. 2C shows an example of flip-chip mounting in which solder ball 15 is used for the connection between processor chip 1 and frame 6. When flip-chip mounting is performed, although processor chip 1 and trace chip 10 sandwich respective substrate 3, signal communication using electromagnetic induction enables non-contact signal communication, thereby realizing tracing.

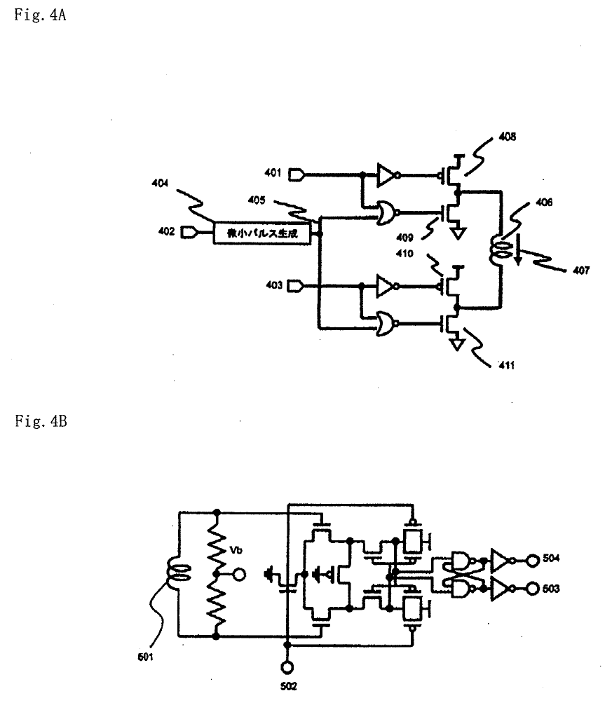

FIG. 3 is a block diagram to conceptually show the configuration within processor core 1. The information to be traced is assumed to be, for example, data from processor core 2 to cache 4, addresses at which data are stored, and the control signal of the processor core. Each item of information is sent to the trace chip by non-contact signal communication mechanism 12A.

This non-contact signal communication mechanism 12A includes switch 12ASW, transmitter 12ATX, and transmission coil 12AL.

When a trace signal for debugging is created, switch 12ASW is short circuited so that a signal is inputted to transmitter 12ATX. Transmitter 12ATX performs signal transmission to trace chip 10 by sending a current signal in conjunction with the input data to transmission coil 12AL.

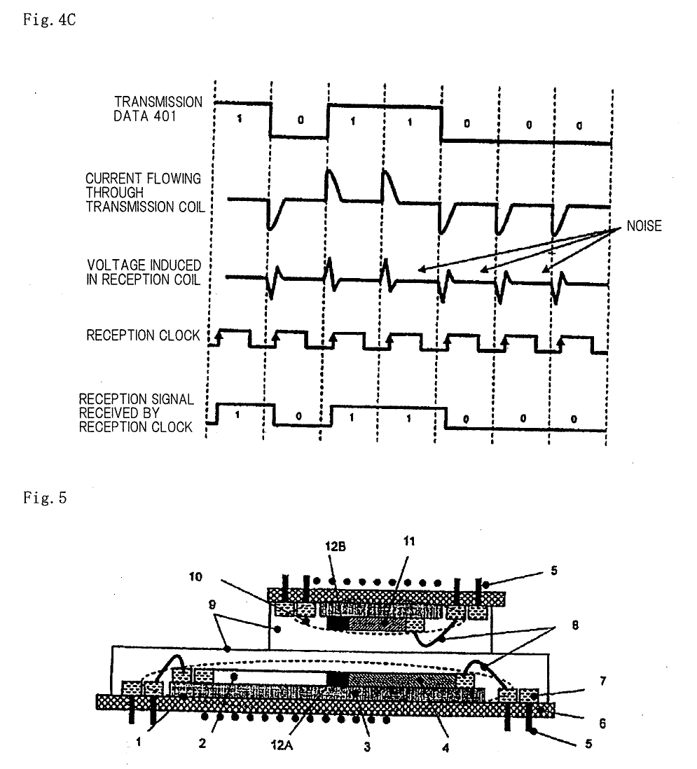

FIG. 4A is a circuit diagram of wireless signal transmission mechanism transmission circuit 12ATX; FIG. 4B is a circuit diagram of reception circuit 12BRX; and FIG. 4C is a waveform diagram to show the operations thereof. Transmission coil 406 in FIG. 4A is shown to be the same as transmission coil 12AL in FIG. 3. Moreover, reception circuit 12BRX is included in non-contact signal communication mechanism (reception) 12B.

### Second Exemplary Embodiment

FIG. 5 shows a second exemplary embodiment. In the first exemplary embodiment, the semiconductor device has a SIP structure. The second exemplary embodiment shows the case of a PoP (Package on Package) structure. The semiconductor device of the present exemplary embodiment is made up of a package including processor chip 1 and a package including trace chip 10. When debugging is required after a mass production system is completed, acquisition of a trace signal for debugging is made possible by simply mounting a package including trace chip 10 onto a mass production system.

### Third Exemplary Embodiment

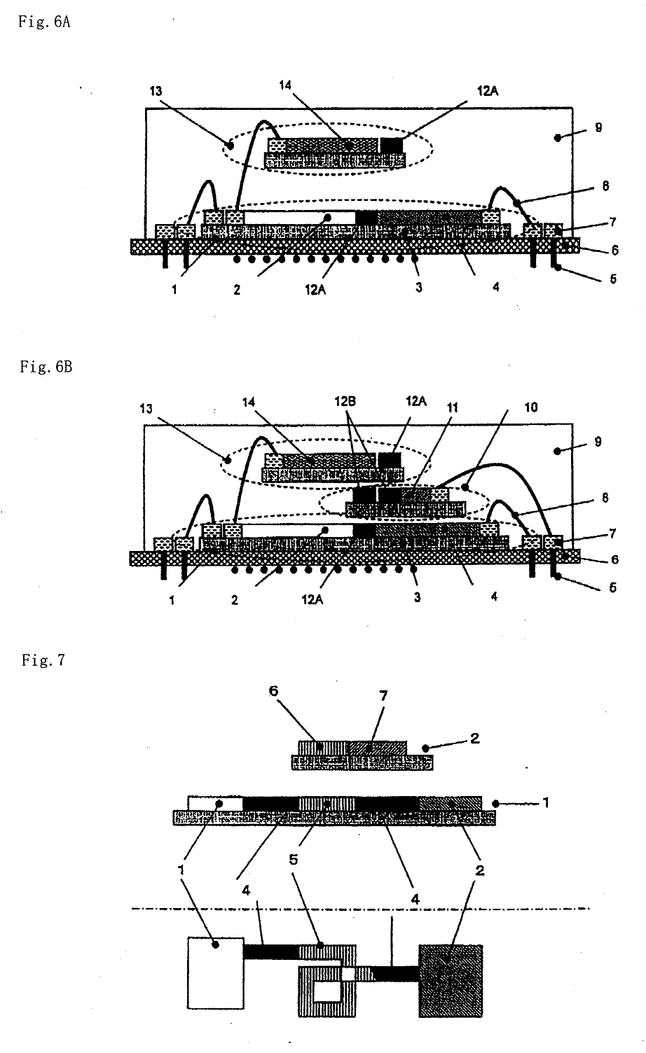

Next, a third exemplary embodiment will be shown. Although the semiconductor device is made up of processor chip 1 alone in the first exemplary embodiment, the third exemplary embodiment 3 is a system made up of processor chip 1 and memory chip 13. FIG. 6A is a sectional view of a mass produced chip which does not include a trace chip. Processor chip 1 and memory chip 13 are connected by using pad 7 and wire 8 to exchange signals.

FIG. 6B is a sectional view when trace chip 10 is provided. As shown in FIG. 6B, trace chip 10 is placed between processor chip 1 and memory chip 13. The connection between trace chip 10, processor chip 1, and memory chip 13 is provided by using non-contact signal communication mechanisms 12A, 12B, as with the first exemplary embodiment.

As shown in FIG. 5, acquiring a trace signal almost without affecting the data path of the bulk product is made possible.

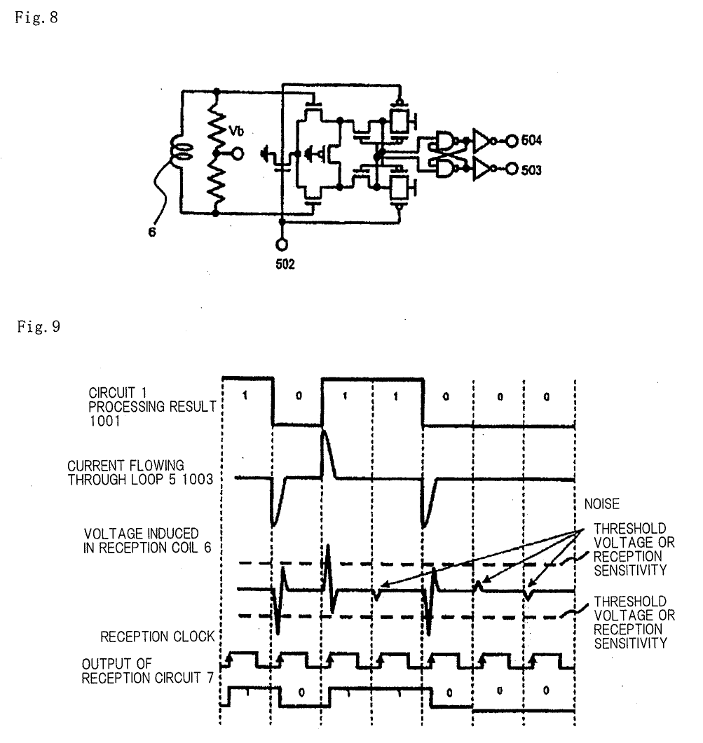

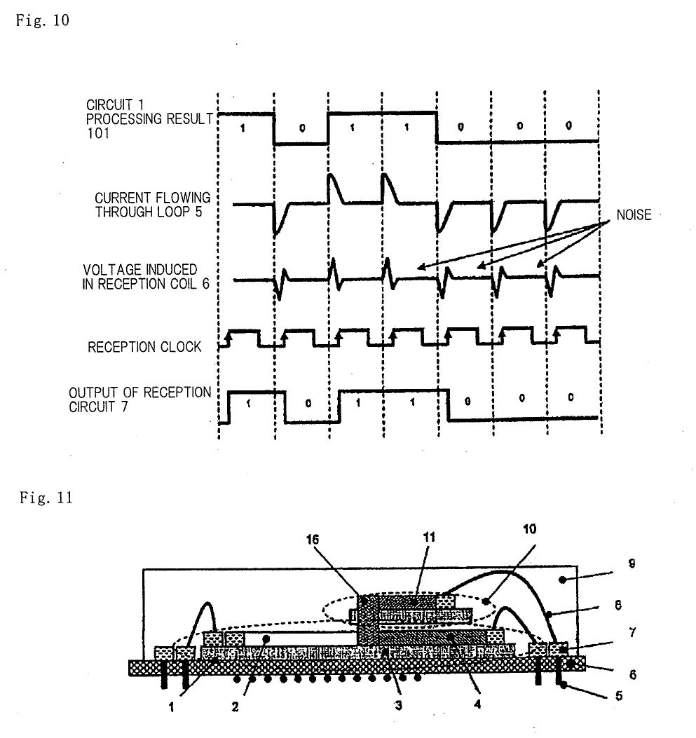

In the above described exemplary embodiment, necessary information for tracing is transmitted to trace chip 10 by adding non-contact signal communication mechanism (transmission) 12A. As a fourth exemplary embodiment, alternative transmission means by non-contact signal communication mechanism (transmission) 12A is shown in FIG. 7. A part of the wiring connecting processor core 2 and cache 4 is formed into a loop shape thereby forming an inductor, which is utilized for electromagnetic induction between the inductor and non-contact signal communication mechanism (reception) 12B formed on trace chip 10. In such a configuration, since there is no circuit newly added to processor chip 1, and since the signal processing conditions during trace signal preparation and normal signal processing are exactly the same, it becomes possible to perform very effective debugging.

When data between processor core 2 and cache 4 are transmitted in a voltage mode, as shown in FIG. 9, reception of transmission data is enabled showing that signal transmission is being correctly performed.

Further, when the data is transmitted in a current mode, a similar waveform to that in FIG. 4C is obtained showing that signal transmission has been correctly performed.

### Fourth Exemplary Embodiment

FIG. 7 is a sectional view to show a first exemplary embodiment of the present invention. The semiconductor device in the resent exemplary embodiment has a SIP (System in Package) configuration, and includes circuit 1 for performing signal processing, circuit 2 into which the processing result is inputted, and wiring 4 for connecting circuit 1 and circuit 2. The wiring connecting each circuit includes one or more loops 5. Another chip 2 which receives the processing result of circuit 1 is implemented on the top part of chip 1, and loop 5 formed on chip 1 and reception coil 6 formed on chip 2 are formed at about the same position.

When the processing result of circuit 1 is inputted to wiring 4, the internal state of the wiring changes and current flows in wiring 4 and loop 5. At that time, electromagnetic induction is generated between loop 5 and reception coil 6; the change of the magnetic flux thereof causes electromagnetic induction to the second chip; and by observing the signal caused by electromagnetic induction with the second chip, it becomes possible to transmit the signal from the first chip.

Further, this signal transmission can also be used to monitor the internal state of chip 1. In this respect, FIG. 8 shows an example of circuit diagram of reception coil 6 and reception circuit 7. Further, FIG. 9 shows the current flowing through loop 5, the signal generated at reception coil 6, and the reception result of reception circuit 7 when the output of circuit 1 is in a voltage mode. Further, FIG. 20 shows the result when the output of circuit 1 is in a current mode, which is similar to the result of FIG. 4C.

As shown in FIGS. 9 and 20, reception circuit 7 of chip 2 receives the processing result of circuit 1 showing that monitoring of signal transmission and the internal state of chip 1 is possible.

According to the present exemplary embodiment, a signal from one chip can be transmitted not only to the same chip, but also to other chips. Further, simultaneous transmission from one chip to a plurality of other chips becomes possible. Conventionally, for signal transmission to other chips, there was no other way but to use wire bonding, which requires a large sacrifice of the area; however, the present exemplary embodiment enables signal transmission to a plurality of other chips by utilizing the coil which is used for signal transmission between circuits and further by vertically placing one coil on top of another. The same effect also can be achieved not only by the coil used for signal transmission between circuits, but also by the coil used for signal transmission between chips.

Next, a signal transmission method for transmitting a signal between processor chip 1 and trace chip 10 using alternative means will be mentioned.

Although, signal transmission utilizing electromagnetic induction has been used so far, signal transmission will not be limited to this method, but signal transmission between laminated chips may also be used.

As the fourth exemplary embodiment, a semiconductor device which utilizes a through electrode for signal communication between chips is shown in FIG. 21. Through electrode 16 is a technique to form an electrical transmission path from the chip front face to the chip back face by providing a hole that penetrates through the chip substrate and by filling the hole with conductive substance. Connecting electrical transmission paths formed between multiple chips enables signal transmission. Further, besides through electrodes, signal transmission techniques utilizing capacitive coupling between electrodes may also be used.

1-15. (canceled)

16. A semiconductor device, characterized by comprising:
at least one or more kinds of first chips equipped with a circuit for performing data processing; and
a second chip equipped with a circuit for tracing the operation of said circuit equipped in the first chip, wherein
a signal between said first chip and said second chip is transmitted by signal transmission utilizing electromagnetic induction.

17. A semiconductor device, characterized by comprising:
at least one or more kinds of first chips;
at least one or more third chips equipped with a storage circuit in which data to be used by the first chip is stored; and
a second chip equipped with a circuit for tracing the operation of said circuit installed in the first chip and for tracing a signal between said first chip and said third chip, wherein
a signal between said first chip and said second chip is transmitted by signal transmission utilizing electromagnetic induction.

18. The semiconductor device according to claim 16, characterized in that
a loop is formed of a part of a wiring through which a signal of said first chip to be monitored by said second chip flows, and an inductor is formed at a position corresponding to said loop of said second chip.

19. The semiconductor device according to claim 17, characterized in that
a loop is formed of a part of a wiring through which a signal of said first chip to be monitored by said second chip flows, and an inductor is formed at a position corresponding to said loop of said second chip.

20. The semiconductor device according to claim 16, characterized in that
power supply to said second chip is provided without power passing through said first chip or said second chip, or both of them.

21. The semiconductor device according to claim 17, characterized in that
power supply to said second chip is provided without power passing through said first chip or said second chip, or both of them.

22. The semiconductor device according to claim 16, characterized in that
said second chip is sealed in a separate package different from a package in which said first chip or said third chip is sealed, or different from a package in which both said first chip and said third chip are sealed.

23. The semiconductor device according to claim 17, characterized in that
said second chip is sealed in a separate package different from a package in which said first chip or said third chip is sealed, or different from a package in which both said first chip and said third chip are sealed.

24. The semiconductor device according to claim 16, characterized in that
signal transmission between chips is performed by an electric transmission path penetrating a chip substrate.

25. The semiconductor device according to claim 17, characterized in that
signal transmission between chips is performed by an electric transmission path penetrating a chip substrate.

26. The semiconductor device according to claim 16, characterized in that
signal transmission between chips is performed by signal transmission utilizing a capacitive couple between electrodes formed between the chips.

27. The semiconductor device according to claim 17, characterized in that
signal transmission between chips is performed by signal transmission utilizing a capacitive couple between electrodes formed between the chips.

28. A semiconductor device, including
at least one or more first circuits for transmitting data;
at least one or more second circuits for receiving said data; and
first signal transmission means for performing signal transmission from said first circuit to said second circuit,
said semiconductor device characterized by comprising
at least one or more third circuits for performing signal transmission by electromagnetic induction through said first signal transmission means.

29. The semiconductor device according to claim 28, characterized in that
said first circuit and the second circuit are included in a same first chip, and said third chip is included in a second chip.

30. The semiconductor device according to claim 28, characterized in that
said first circuit is included in a first chip, said second chip is included in a third chip, and said third chip is included in a second chip.

31. The semiconductor device according to claim 28, characterized in that
said third circuit has second signal transmission means, and said first and second signal transmission means are electromagnetic induction coils arranged one on top of another.

32. The semiconductor device according to claim 29, characterized in that
said third circuit has second signal transmission means, and said first and second signal transmission means are electromagnetic induction coils arranged one on top of another.

33. The semiconductor device according to claim 30, characterized in that
said third circuit has second signal transmission means, and said first and second signal transmission means are electromagnetic induction coils arranged one on top of another.
